(19) United States
(12) Patent Application Publication
(10) Pub. No.: US 2024/0306391 A1
(43) Pub. Date: Sep. 12, 2024

(54) CONTACT CONSTRUCTION FOR SEMICONDUCTOR DEVICES WITH LOW-DIMENSIONAL MATERIALS

(71) Applicant: Applied Materials, Inc., Santa Clara, CA (US)

(72) Inventors: Hao-Ling Tang, Campbell, CA (US); Arvind Kumar, Austin, TX (US); Mahendra Pakala, Saratoga, CA (US); Keith Tatseun Wong, North Bend, WA (US); Yi-Hsuan Hsiao, San Jose, CA (US); Dongqing Yang, Pleasanton, CA (US); Mark Conrad, Cohoes, NY (US); Rio Soedibyo, Ballston Spa, NY (US); Minrui Yu, San Jose, CA (US)

(73) Assignee: Applied Materials, Inc., Santa Clara, CA (US)

(21) Appl. No.: 18/597,057

(22) Filed: Mar. 6, 2024

Related U.S. Application Data
(60) Provisional application No. 63/488,711, filed on Mar. 6, 2023.

(51) Int. Cl. H10B 43/27; H10B 43/35

(52) U.S. Cl. CPC H10B 43/27; H10B 43/35

(57) ABSTRACT

Two-dimensional (2D) materials formed in very thin layers improve the operation of semiconductor devices. However, forming a contact on 2D material tends to damage and penetrate the 2D material. A relatively gentle etch process has been developed that is very selective to the 2D material and allows vertical holes to be etched down to the 2D material without damaging or penetrating the 2D material. A low-power deposition process forms a protective liner when performing the metal fill to further prevent damage to the 2D material when forming the metal contacts in the holes. These processes allow a vertical metal contact to be formed on a planar 2D material or a vertical sidewall contact be formed in a 3D NAND without damaging the 2D material. This increases the contact area, reduces the contact resistance, and improves the performance of the 2D material in the device.

### CROSS-REFERENCES TO RELATED APPLICATIONS

This application claims the benefit of U.S. Provisional Application No. 63/488,711 filed on Mar. 6, 2023 entitled “CONTACT CONSTRUCTION FOR SEMICONDUCTOR DEVICES COMPRISING LOW DIMENSIONAL MATERIALS,” which is incorporated herein by reference.

### TECHNICAL FIELD

The present technology relates to semiconductor systems, processes, and equipment. More specifically, the present technology relates to processes and systems for forming conductive contacts with low-dimensional materials in semiconductor devices.

### BACKGROUND

Integrated circuits are made possible by processes which produce intricately patterned material layers on substrate surfaces. Producing patterned material on a substrate requires controlled methods for forming and removing material. As device sizes continue to reduce, features within the integrated circuits may get smaller and aspect ratios of structures may grow, and maintaining dimensions of these structures during processing operations may be challenged. Additionally, new materials are now being used that require special engineering and manufacturing techniques. For example, two-dimensional (2D) materials can have thicknesses as small as just a few atoms arranged in a 2D structure. In semiconductor devices, these materials exhibit desirable surface effects and unique quantum mechanical characteristics. For example, graphene has a very high conductivity, while transition metal dichalcogenides (TMDs) may be used to construct device components with tunable bandgaps. However, due to their small size and fragile nature, these 2D materials are very difficult to work with.

### SUMMARY

In some embodiments, a semiconductor device may include a channel layer comprising a two-dimensional (2D) material and forming a channel for the semiconductor device; an insulating layer formed over the channel layer, where the insulating layer may define a feature that extends through the insulating layer down to the channel layer; and a metal that fills the feature, where the metal may contact a top surface of the 2D material of the channel layer.

In some embodiments, a semiconductor device may include a vertical channel hole defined in the semiconductor device; a 2D material that conformally lines the vertical channel hole; and a metal in the vertical channel hole that contacts the 2D material and forms an electrode for the semiconductor device.

In some embodiments, a method of forming a semiconductor device may include forming a layer of a 2D material; forming a layer of an insulating material on the 2D material; etching away a portion of the insulating material to form a feature and expose a surface of the 2D material; and filling the feature with a metal, wherein the metal contacts the surface of the 2D material.

In any embodiments, any and all of the following features may be implemented in any combination and without limitation. The metal may contact the top surface of the 2D material without penetrating or damaging the 2D material. The 2D material may include a Transition-Metal Dichalcogenide (TMD) monolayer or bilayer. The 2D material may include a monolayer or bilayer of molybdenum disulfide (MoS₂). The channel layer may form a planar channel layer, and the metal forms a drain or source for the semiconductor device. A vertical side of the channel layer may be free of contact with the metal. The metal may contact the 2D material without penetrating or damaging the 2D material. The metal may substantially fill the vertical channel hole inside of the 2D material. The 2D material may also conformally line a top surface of the semiconductor device between vertical channel holes. The semiconductor device may also include an oxide layer that fills a portion of the vertical channel hole below the metal. Etching away the portion of the insulating material may include performing a plasma-free vapor etch. Etching away the portion of the insulating material may include maintaining a temperature of less than or about 45° C. such that 2D material is free of oxidation. Etching away the portion of the insulating material may include providing an HF etch gas with an NH3 carrier gas with a flow rate ratio of approximately 1:1. Etching away the portion of the insulating material may include increasing a temperature of the semiconductor device by moving the semiconductor device closer to a top plate of a processing chamber and performing an anneal of between about 110° C. and about 130° C. Filling the feature with the metal may include a target tilt angle of between about 30° and about 40°. Filling the feature with the metal may include forming a metal liner using a physical vapor deposition (PVD) process performed with a power that is less than or about 500 W and a pressure less than or about 0.1 Torr; and filling the feature with a metal fill material. The semiconductor device may include a planar device, the feature may include a vertical hole with the 2D material exposed at a bottom of the vertical hole, and the metal may fill the vertical hole to form an electrode of the semiconductor device. The semiconductor device may include a three-dimensional (3D) NAND memory device, the feature may include a vertical channel hole that is conformally lined with the 2D material, and the metal may substantially fill the vertical channel hole inside of the 2D material.

### BRIEF DESCRIPTION OF THE DRAWINGS

A further understanding of the nature and advantages of various embodiments may be realized by reference to the remaining portions of the specification and the drawings, wherein like reference numerals are used throughout the several drawings to refer to similar components. In some instances, a sub-label is associated with a reference numeral to denote one of multiple similar components. When reference is made to a reference numeral without specification to an existing sub-label, it is intended to refer to all such multiple similar components.

FIG. 1 shows a top plan view of one embodiment of a processing system of deposition, etching, baking, and curing chambers that may be included or configured according to some embodiments of the present technology.

FIG. 2A illustrates a semiconductor device 200 utilizing 2D materials, according to some embodiments.

FIG. 2B illustrates how a layer of 2D materials can be damaged when etching an overlying layer and depositing metal contacts.

FIG. 3 illustrates a flowchart of a method for forming a semiconductor device using 2D materials, according to some embodiments.

FIG. 4A illustrates a 2D material formed on a substrate, according to some embodiments.

FIG. 4B illustrates an insulating material formed over the 2D material, according to some embodiments.

FIG. 4C illustrates an etch process that is selective to the 2D material, according to some embodiments.

FIG. 4D illustrates the formation of a liner in the feature to contact the 2D material, according to some embodiments.

FIG. 4E illustrates a metal fill operation, according to some embodiments.

FIG. 4F illustrates an example of the semiconductor device with additional components, according to some embodiments.

FIG. 5A illustrates the formation of a 2D material in a channel hole of a semiconductor device, according to some embodiments.

FIG. 5B illustrates an insulating material that is formed on the 2D material, according to some embodiments.

FIG. 5C illustrates an etch process that may be used to remove a portion of the insulating material from the semiconductor device according to some embodiments.

FIG. 5D illustrates how a metal may substantially fill the vertical channel hole inside of the 2D material, according to some embodiments.

### DETAILED DESCRIPTION

Two-dimensional (2D) materials may be formed in very thin layers and may improve the operation of semiconductor devices, such as channels in transistors or memory devices. However, forming a vertical contact on a top surface of the 2D material is very difficult, as the etch process to define the contact hole and the deposition of the metal both tend to damage and penetrate the 2D material. A relatively gentle etch process has been developed that is very selective to the 2D material and allows vertical holes to be etched down to the 2D material without damaging or penetrating the 2D material. A low-power deposition process forms a protective liner when performing the metal fill to further prevent damage to the 2D material when forming the metal contacts. These processes allow a vertical metal contact to be formed on a planar 2D material or a vertical sidewall contact be formed in a three-dimensional (3D) NAND without damaging the 2D material. This increases the contact area, reduces the contact resistance, and improves the performance of the 2D material in the device.

Although the remaining disclosure will routinely identify specific etching and deposition processes utilizing the disclosed technology, it will be readily understood that the systems and methods are equally applicable to a variety of other processes as may occur in the described chambers. Accordingly, the technology should not be considered to be so limited as for use with the described etching or deposition processes alone. The disclosure will discuss one possible system that can be used with the present technology before describing systems and methods or operations of exemplary process sequences according to some embodiments of the present technology. It is to be understood that the technology is not limited to the equipment described, and processes discussed may be performed in any number of processing chambers and systems.

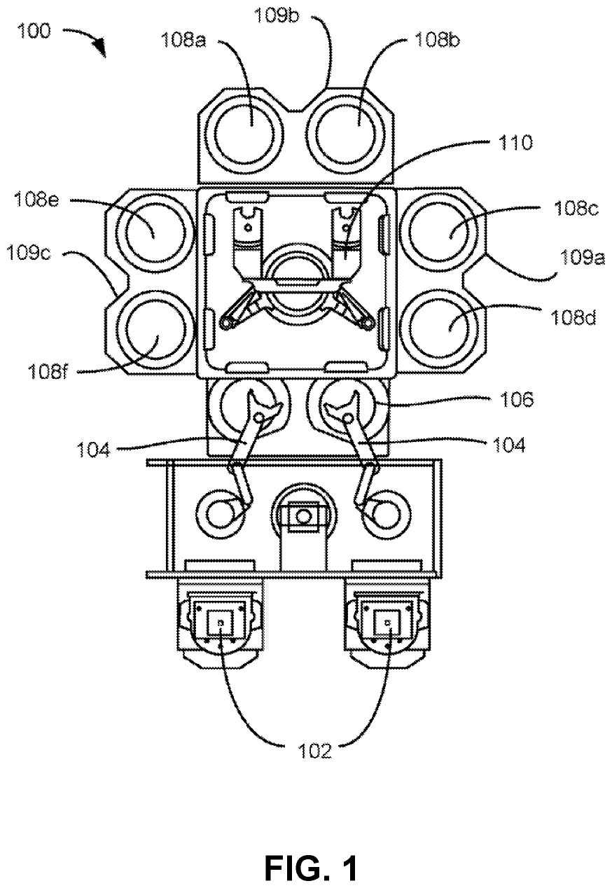

FIG. 1 shows a top plan view of one embodiment of a processing system 100 of deposition, etching, polishing, baking, and curing chambers that may be included or configured according to some embodiments of the present technology. In the figure, a pair of front opening unified pods 102 supply substrates of a variety of sizes that are received by robotic arms 104 and placed into a low pressure holding area 106 before being placed into one of the substrate processing chambers 108a-f, positioned in tandem sections 109a-c. A second robotic arm 110 may be used to transport the substrate wafers from the holding area 106 to the substrate processing chambers 108a-f and back. Each substrate processing chamber 108a-f, can be outfitted to perform a number of substrate processing operations including the dry etch processes described herein in addition to cyclical layer deposition, atomic layer deposition, chemical vapor deposition, physical vapor deposition, etch, pre-clean, anneal, plasma processing, degas, orientation, and other substrate processes.

The substrate processing chambers 108a-f may include one or more system components for depositing, annealing, curing and/or etching a material film on the substrate or wafer. In one configuration, two pairs of the processing chambers, for example 108c-d and 108e-f, may be used to deposit material on the substrate, and the third pair of processing chambers, for example 108a-b, may be used to cure, anneal, or treat the deposited films. In another configuration, all three pairs of chambers, for example 108a-f, may be configured to both deposit and cure a film on the substrate. Any one or more of the processes described may be carried out in additional chambers separated from the fabrication system shown in different embodiments. It will be appreciated that additional configurations of deposition, etching, annealing, and curing chambers for material films are contemplated by system 100. Additionally, any number of other processing systems may be utilized with the present technology, which may incorporate chambers for performing any of the specific operations. In some embodiments, chamber systems which may provide access to multiple processing chambers while maintaining a vacuum environment in various sections, such as the noted holding and transfer areas, may allow operations to be performed in multiple chambers while maintaining a particular vacuum environment between discrete processes.

The system 100, or more specifically chambers incorporated into system 100 or other processing systems, may be used to produce structures according to some embodiments of the present technology. For example, the system 100 may be used to perform deposition processes, chemical mechanical polishing (CMP) processes, etch processes, and so forth to form a memory device, an array of memory devices, or any other semiconductor device. In particular, the example structures described below including the transistor and 3D NAND may be formed using any of the chambers in the system 100.

Some 2D materials are being incorporated into semiconductor devices to improve their performance. In general, 2D materials may include crystalline solids formed in a single layer of atoms. For example, one subset of 2D materials may include transition-metal dichalcogenide (TMD) monolayers that include atomically thin semiconductors. These TMD monolayers may include a transitional metal atom, such as molybdenum, tungsten, etc. The metal atoms are bonded with chalcogen atoms, such as sulfur, selenium, tellurium, etc. These TMD materials are notable for their extremely thin layer size. For example, a molybdenum disulfide (MoS₂) monolayer is approximately 6.5 Å thick. These 2D materials are emerging as promising alternatives when forming different portions of semiconductor devices. For example, 2D materials may offer certain advantages when used to form a channel of a transistor or other similar device. A field-effect transistor (FET) with a channel formed from an MoS₂ monolayer or bilayer may exhibit a very large on/off ratio at room temperature due to the electrostatic control these materials provide over conduction in the 2D channel. These materials also provide advantages related to electron mobility and bandgap characteristics. Furthermore, the use of 2D materials is desirable because they are extremely thin, which is important when shrinking size is a driving factor in device design.

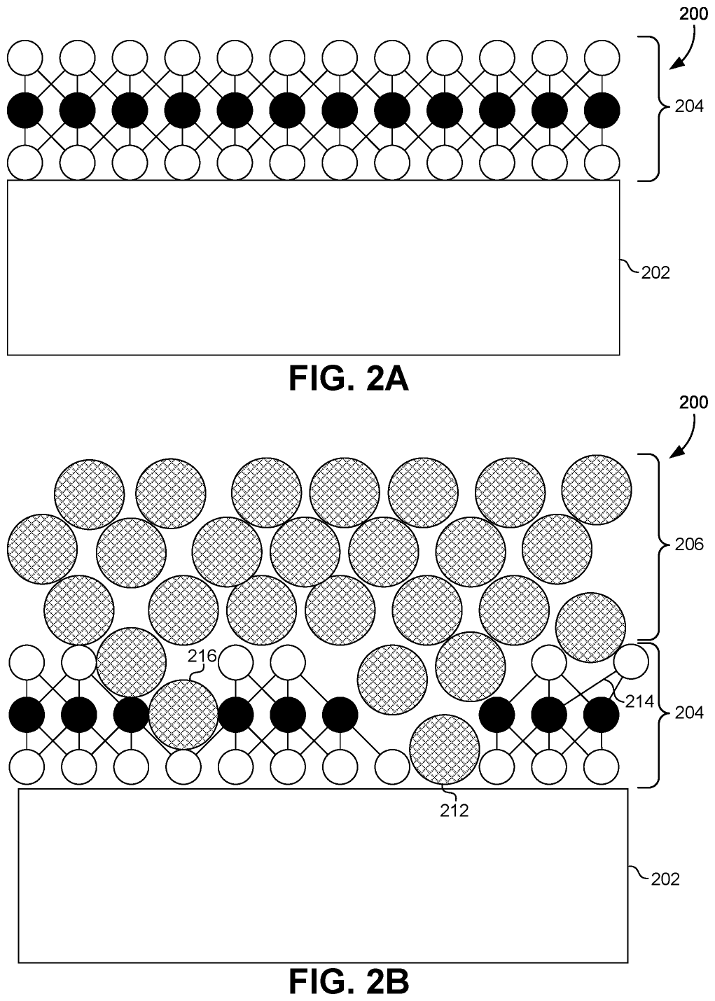

FIG. 2A illustrates a semiconductor device 200 utilizing 2D materials, according to some embodiments. The semiconductor device 200 may include substrate 202. The substrate 202 may include any type of semiconductor substrate, including silicon, polysilicon, glass, or other materials. Additionally, the substrate 202 may include multiple layers that are not explicitly shown in FIG. 2A. For example, the substrate 202 may include dielectric layers, doped silicon layers, metal layers, and other features that may be part of the semiconductor device 200. Functionally, the substrate 202 may form a surface on which the 2D materials may be formed with any underlying layers abstracted for the sake of clarity.

The semiconductor device 200 may include a layer comprising 2D materials 204. For example, the 2D materials 204 may include a TMD layer, such as MoS₂. The MoS₂ may include a unit of one layer molybdenum atoms covalently bonded to two layers of sulfur atoms. Although FIG. 2A only illustrates a single monolayer of MoS₂, other embodiments may include multiple monolayers without restriction, such as a bilayer, etc. However, as a number of layers decreases, the bandgap increases, which may provide advantages to the operation of the semiconductor device 200.

While the 2D materials 204 may be readily formed on the substrate 202, there are number of technical problems that exist when attempting to interface the 2D materials 204 with a metal contact. Specifically, existing techniques cannot etch through a material above the 2D materials 204 without also etching the 2D materials 204 themselves. In a planar device, the layer of 2D materials 204 maybe formed on the substrate 202. Next, an insulating layer, such as an interlayer dielectric (e.g., silicon oxide), may be formed on top of the layer of 2D materials 204. Features may then be etched in the insulating layer to form the locations for the metal contacts and to expose a top surface of the 2D materials 204. However, existing etch processes have been shown to damage the 2D materials 204, which may affect the subsequent performance of the semiconductor device 200.

FIG. 2B illustrates how a layer of 2D materials can be damaged when etching an overlying layer and depositing metal contacts. Recall that the 2D materials 204 are relatively thin. For example, a monolayer of MoS₂ may have a thickness of approximately 0.7 nm, and a bilayer may have a thickness of approximately 1.4 nm. Existing etch techniques tend to etch into the 2D materials. Additionally, even gentle deposition techniques when forming the metal contacts may also damage the 2D materials 204. FIG. 2B illustrates a metal material 206 deposited with an evaporation technique using physical deposition without a plasma. However, even this deposition technique shows defects 216 in the surface of the 2D materials 204, diffusion of the metal material 206 through the 2D materials 204, and straining of the covalent bonds 214 in the 2D material 204.

Because of this difficulty, existing techniques for interfacing a metal contact with the 2D materials 204 typically a surface of the 2D materials. Instead, existing techniques may attempt alternatives, such as etching through a portion of planar 2D materials 204 to expose a vertical sidewall of the 2D materials 204. The metal contact may then be deposited next to the exposed vertical sidewall of the 2D materials 204. However, this creates a very small interface between the metal and the planar 2D materials 204, since the planar 2D materials 204 are very thin. Alternatively, the metal contacts may be formed first on the substrate 202, and a layer of the 2D materials may be formed separately and transferred onto the metal contacts. For example, the layer of the 2D materials 204 may then be separated and placed on top of the metal contacts. However, this technique cannot be used for typical manufacturing processes or devices, such as vertical 3D NAND devices. Some techniques avoid etching layers above the 2D materials 204 by depositing patterned photoresist on the 2D materials 204. The metal layer may then be deposited over the 2D materials 204 and the photoresist layer. When the photoresist is removed with the overlying portions of the metal layer, the remaining metal on the 2D materials 204 may form the contacts. However, this process is not typically compatible with industrial processes for forming memories and other semiconductor devices, and the deposition process may still damage the 2D materials 204. No existing solutions provide a reliable top contact between a 2D material and a metal without damaging the 2D material that is compatible with standard manufacturing processes.

The embodiments described herein solve these and other technical problems by using an etch process specifically designed to stop at the surface of the 2D materials without penetrating or damaging the 2D materials. Additionally, these embodiments use a metal-fill process designed to gently deposit a metal on the 2D materials without damaging or penetrating the surface of the 2D materials. These techniques are compatible planar devices, where the 2D materials may be formed on a layer of the substrate first, then covered with insulating material, such as an interlayer dielectric. A hole in the insulating material may then be etched away to expose the 2D materials, and a metal-fill process may deposit the metal contacts on top of the 2D materials without penetrating or damaging the 2D materials. These techniques are also compatible with vertical devices, such as 3D NAND devices. For example, the 2D materials may be conformally formed as a liner on vertical sidewalls of a channel hole for a memory device. The hole may be filled with insulating material, and the insulating material may then be etched away from the hole to expose a portion of the 2D material. The hole may then be filled with the metal to form a contact with the 2D material.

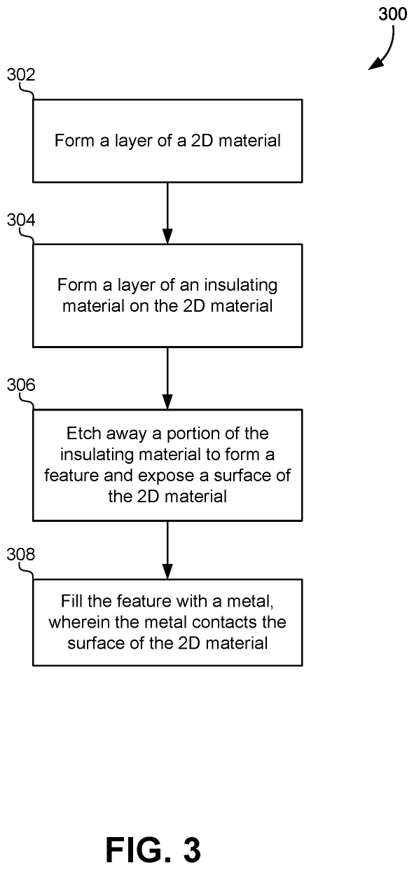

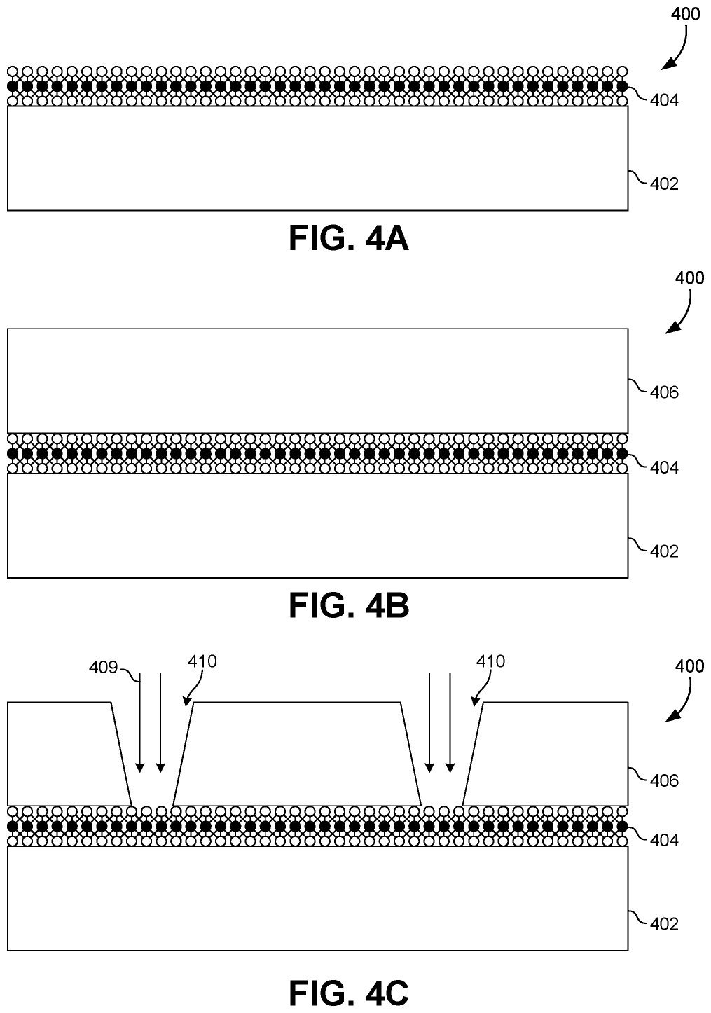

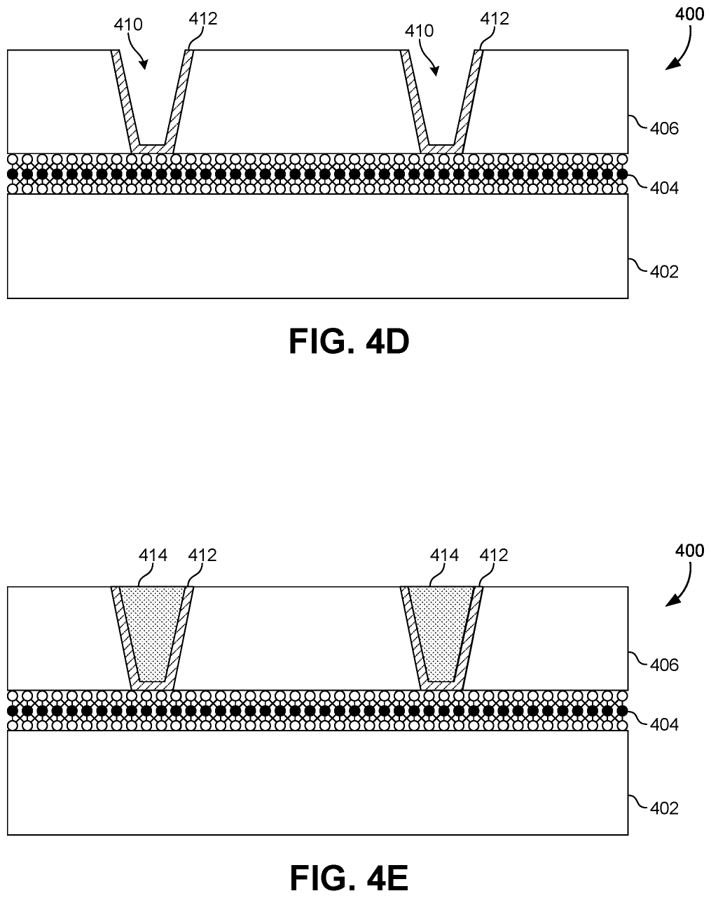

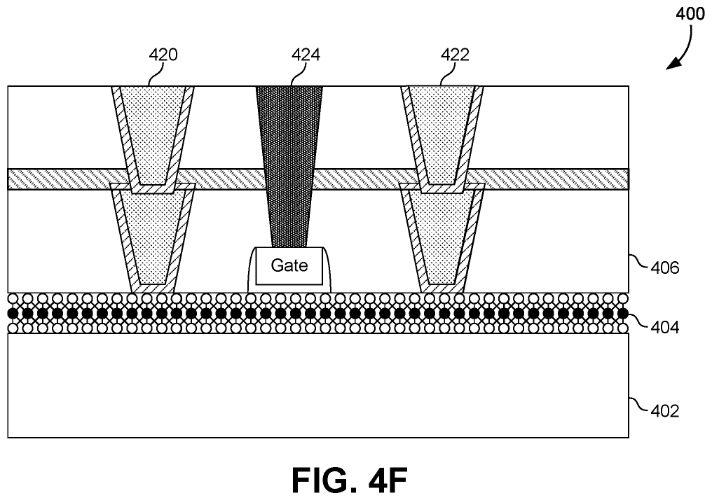

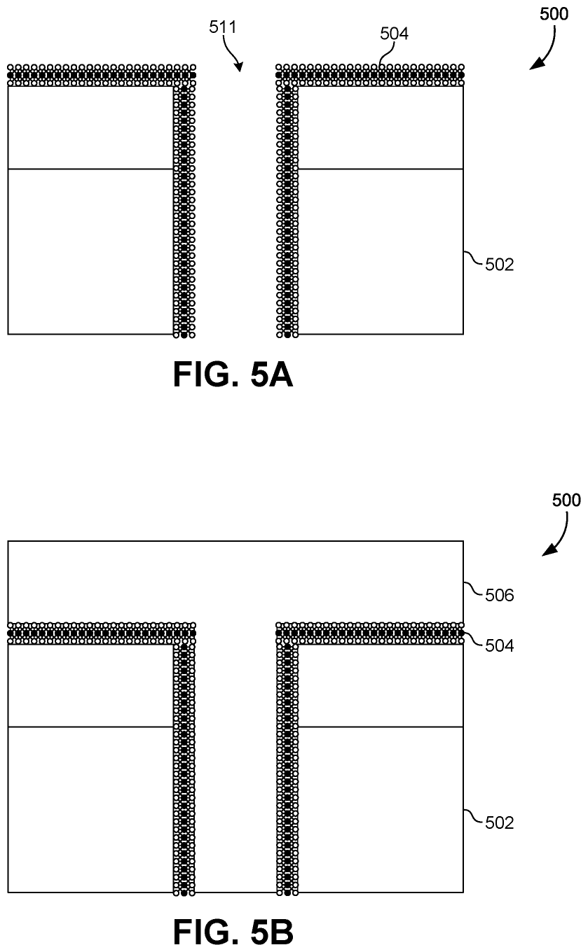

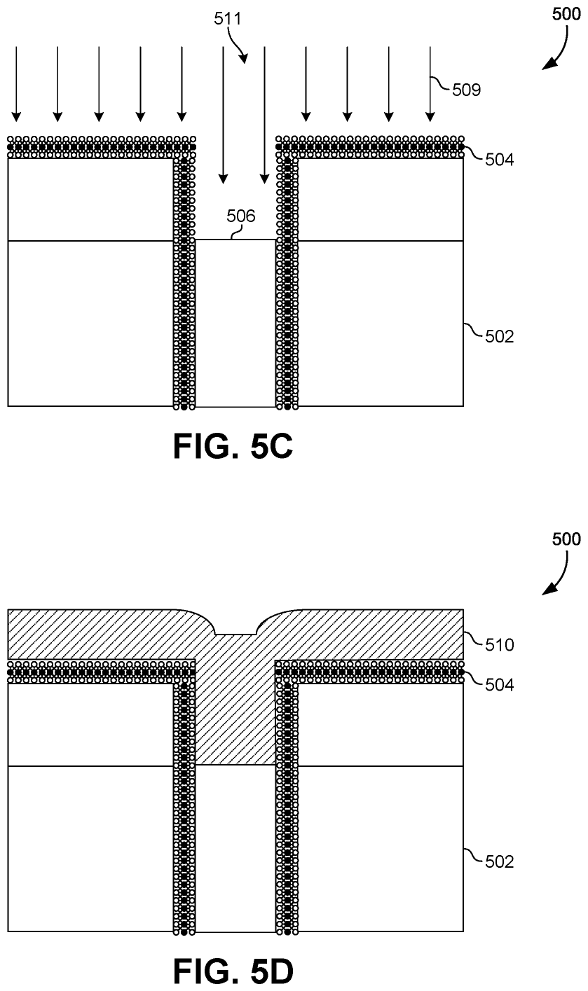

FIG. 3 illustrates a flowchart of a method 300 for forming a semiconductor device using 2D materials, according to some embodiments. This method 300 may be performed by one or more of the chambers in the processing system 100 described above in relation to FIG. 1. Additionally, this method 300 may be used to fabricate both planar and vertical 3D devices. In order to illustrate each of these steps, FIGS. 4A-4F illustrate the formation of a planar device, and FIGS. 5A-5D illustrate the formation of a 3D vertical device. References are made to the example structures shown in these figures when describing the operations of the method 300. However, these structures are provided only by way of example and are not meant to be limiting. Many other types of structures are compatible with this method 300.

The method 300 may include forming a layer of a 2D material (302). FIG. 4A illustrates a 2D material 404 formed on a substrate 402, according to some embodiments. As described above, the substrate 402 may include any number of underlying layers that are not shown specifically in FIG. 4A. These layers may include doped n-wells, doped p-wells, wiring in metal layers, insulating layers, conductive layers, interconnect layers, and/or any other type of layer present on modern semiconductor wafers. By way of example, the 2D materials 204 may include a TMD material such as MoS₂. However, any other type of 2D material 204 may be used unless stated otherwise. For example, while MoS₂ exhibits distinct advantages in some semiconductor device, other devices may use tungsten disulfide or similar materials that may have other advantages.

The method 300 may also include forming a layer of an insulating material on the 2D material (304). FIG. 4B illustrates an insulating material 406 formed over the 2D material 204, according to some embodiments. In some processes, the insulating material 406 may be formed directly on top of the 2D material 204, such that the 2D material 404 physically contacts the insulating material 406 with no intervening layers in between. Note that trace amounts of other materials may be present. In other processes, the insulating material 406 may include multiple layers of different materials that are not shown explicitly in FIG. 4B. The insulating material 406 may include any type of interlayer dielectric, such as silicon dioxide or other oxides.

The method 300 may additionally include etching away a portion of the insulating material to form features 410 and expose a surface of the 2D material (306). A pattern may be formed on the insulating material 406 in order to define the regions for the metal contacts. For example, a photoresist pattern may be formed on top of the insulating material 406. The photoresist pattern may include openings where the metal contacts will be formed. The photoresist pattern may be later removed after the etch process is complete.

FIG. 4C illustrates an etch process 409 that is selective to the 2D material 404, according to some embodiments. The etch process 409 may be specifically tailored to be selective to the 2D material 404. In other words, the etch process 409 may be configured to readily etch the insulating material 406 without over-etching past the surface of the 2D material 404. In some embodiments, the etch process 409 may be implemented using a vapor etch. Specifically, these embodiments may avoid using a liquid etch since a liquid etch is harder to control. The vapor etch may be very gentle in comparison to the liquid etch, and may thereby minimize any damage to the 2D material 404. Additionally, some embodiments may also perform the vapor etch without a plasma present in the processing chamber. By using a plasma-free process, the etch may be further controlled to prevent etching into the 2D materials 404.

The etch process may be used to form features 410 in the insulating material 406. These features 410 may define a volume or region for the metal contacts. The features 410 may extend from a top surface of the insulating material 406 down to a top surface of the 2D material 404. The features 410 may not extend below the top surface of the 2D material 404 such that the 2D material 404 is not damaged or penetrated by the etch process 409. The dimensions of the features 410 may vary based on the type of embodiment (e.g., the type of memory or semiconductor device). For example, the features 410 may typically have a critical dimension (depth:diameter) of greater than or about 10:1. For example, the hole depth may range from about 200 nm to about 500 nm, while the hole diameter may range from about 20 nm to about 40 nm.

In addition to using a plasma-free vapor etch, some embodiments may use an etch chemistry that is very selective to the 2D material 404. For example, it has been discovered that an HF vapor etch is very selective to 2D material 404 such as MoS₂. To perform the etch, the HF gas may be provided with a carrier gas. The carrier gas may include NH₃ or other similar gases such as argon, helium, hydrogen, and so forth. The flow rate ratio of the etchant gas and the carrier gas may be approximately 1:1. Flow rates of the etchant gas and/or the carrier gas may vary from between about 10 sccm to about 1000 sccm. For example, the flow rates may be between about 10 sccm and about 100 sccm, between about 100 sccm and about 200 sccm, between about 200 sccm and about 300 sccm, between about 300 sccm and about 400 sccm, between about 400 sccm and about 500 sccm, between about 500 sccm and about 600 sccm, between about 600 sccm and about 700 sccm, between about 700 sccm and about 800 sccm, between about 800 sccm and about 900 sccm, between about 900 sccm and about 1000 sccm, and so forth. The flow rates may also include any interval within the intervals described above (e.g., between about 450 sccm and about 650 sccm). The flow rates may also include any individual value within the intervals described above (e.g., about 550 sccm).

Some embodiments may also use a relatively low temperature to better control the etch process 409. The temperature of the substrate during the etch process may range from about 30° C. to about 130° E. For example, the temperature may be between about 30° C. and about 40° C., between about 40° C. and about 50° C., between about 50° C. and about 60° C., between about 60° C. and about 70° C., between about 70° C. and about 80° C., between about 80° C. and about 90° C., between about 90° C. and about 100° C., between about 100° C. and about 110° C., between about 110° C. and about 120° C., between about 120° C. and about 130° C., and so forth. The temperature may also include any interval within the intervals described above (e.g., between about 35° C. and about 55° C.). The temperature may also include any individual value within the intervals described above (e.g., about 45° C.).

The temperature of the top plate or showerhead of the processing chamber may be maintained at a higher temperature (e.g., about 150° C.), and a separation distance between the top plate and the substrate may be increased to bring the temperature of the substrate down to a specified operating temperature (e.g., about 45° C.). The lower temperature ranges described above may prevent oxidation from occurring during the etch process 409. In one processing chamber, the distance between a pedestal supporting the substrate and the showerhead may be maintained at a distance between about 1000 mil to about 2000 mil during the etch process 409. For example, the distance may be between about 1000 mil and about 1200 mil, between about 1200 mil and about 1400 mil, between about 1400 mil and about 1600 mil, between about 1600 mil and about 1800 mil, between about 1800 mil and about 2000 mil, and so forth. The distance may also include any interval within the intervals described above (e.g., between about 1300 mil and about 1700 mil). The distance may also include any individual value within the intervals described above (e.g., about 1500 mil).

In addition to regulating the temperature, some embodiments may also maintain a pressure during the etch process 409 between about 1 Torr and about 10 Torr. For example, the pressure may be between about 1 Torr and about 2 Torr, between about 2 Torr and about 3 Torr, between about 3 Torr and about 4 Torr, between about 4 Torr and about 5 Torr, between about 5 Torr and about 6 Torr, between about 6 Torr and about 7 Torr, between about 7 Torr and about 8 Torr, between about 8 Torr and about 9 Torr, between about 9 Torr and about 10 Torr, and so forth. The pressure may also include any interval within the intervals described above (e.g., between about 4 Torr and about 6 Torr). The pressure may also include any individual value within the intervals described above (e.g., about 5.5 Torr).

In some embodiments, the etch process 409 may include a cyclical etch process that cycles an etch with an anneal. For example, the etchant gas and optional carrier gas may be provided to the processing chamber under the conditions described above for a first time interval. The etchant gas and optional carrier gas may then be purged from the processing chamber, and the temperature of the substrate may be increased for a second time interval to perform the anneal. This cycle may be repeated (e.g., etch, anneal, etch, anneal, etc.) until the surface of the 2D material 404 is exposed. The number of cycles needed may depend on the thickness of the insulating material 406. For example, some embodiments may perform greater than 20 cycles to etch through the insulating material 406. Other embodiments and/or insulating material thicknesses may use between 20 and 30 cycles, between 30 and 40 cycles, between 40 and 50 cycles, between 50 and 60 cycles, between 60 and 70 cycles, and/or more than 70 cycles. This iterative process that includes a thermal anneal is beneficial in preventing byproduct buildup during the etch process 409.

As described above, the temperature of the top plate or showerhead of the processing chamber may be maintained at a higher temperature (e.g., about 150° C.), and a separation distance between the top plate and the substrate may be decreased to bring the temperature of the substrate up to a specified anneal temperature (e.g., about 120° C.). In one processing chamber, the distance between a pedestal supporting the substrate and the showerhead may be maintained at a distance between about 100 mil to about 300 mil during the anneal portion of the etch process 409. For example, the distance may be between about 100 mil and about 150 mil, between about 150 mil and about 200 mil, between about 200 mil and about 250 mil, between about 250 mil and about 300 mil, and so forth. The distance may also include any interval within the intervals described above (e.g., between about 175 mil and about 225 mil). The distance may also include any individual value within the intervals described above (e.g., about 200 mil).

The temperature of the anneal process may be maintained at between about 110° C. and about 130° C. This temperature may be maintained by increasing the temperature in the processing chamber, and/or by moving the substrate closer to a top plate or showerhead of the processing chamber as described above. For example, the temperature may be between about 110° C. and about 115° C., between about 115° C. and about 120° C., between about 120° C. and about 125° C., between about 125° C. and about 130° C., and so forth. The temperature may also include any interval within the intervals described above (e.g., between about 115° C. and about 125° C.). The temperature may also include any individual value within the intervals described above (e.g., about 123° C.).

In addition to regulating the temperature, some embodiments may also maintain a pressure during the anneal portion of the etch process 409 between about 1.0 Torr and about 3.0 Torr. For example, the pressure may be between about 1.0 Torr and about 1.5 Torr, between about 1.5 Torr and about 2.0 Torr, between about 2.0 Torr and about 2.5 Torr, between about 2.5 Torr and about 3.0 Torr, and so forth. The pressure may also include any interval within the intervals described above (e.g., between about 1.5 Torr and about 2.5 Torr). The pressure may also include any individual value within the intervals described above (e.g., about 2.5 Torr).

The duration of the anneal portion of the etch process 409 may be between about 30 seconds and about 90 seconds. For example, the anneal may be between about 30 seconds and about 40 seconds, between about 40 seconds and about 50 seconds, between about 50 seconds and about 60 seconds, between about 60 seconds and about 70 seconds, between about 70 seconds and about 80 seconds, between about 80 seconds and about 90 seconds, and so forth. The time may also include any interval within the intervals described above (e.g., between about 40 seconds and about 60 seconds). The time may also include any individual value within the intervals described above (e.g., about 51 seconds).

Turning back to FIG. 3, after performing the etch process 409, the method may further include filling the feature with a metal (308). Filling the feature with the metal may cause the metal to contact the surface of the 2D material 404. In some embodiments, filling the feature with the metal may include one or more different metal materials. For example, a liner material may first be formed in the features to line the features and contact the 2D material 404. After forming the liner, a metal film may be used to fill the remaining portion of the feature with a metal material inside the liner.

FIG. 4D illustrates the formation of a liner 412 in the feature to contact the 2D material 404, according to some embodiments. As described above, even if the etch process is carefully performed to expose the surface of the 2D material 404 without penetrating or damaging the 2D material 404, the deposition process may also cause damage to the 2D material 404. Therefore, the techniques described below are designed to carefully form the liner 412 without damaging the 2D material 404. In contrast to previous techniques, the vertical sides of the channel layer formed by the 2D material 404. Instead, and much larger contact is made between the metal and the 2D material 404 along a top surface of the 2D material 404.

The deposition process for forming the liner 412 may be configured to be gentler than traditional metal deposition processes. For example, some embodiments may use a physical vapor deposition (PVD) process. The PVD process may be performed without a plasma present to further present damaging the 2D material 404, as a plasma-free PVD process has been shown to be gentle enough not to damage the 2D material 404. Alternatively, some embodiments may use an atomic layer deposition (ALD) process or a chemical vapor deposition process (CVD). However, some ALD/CVD precursors may cause damage to 2D materials such as MoS2.

The liner 412 may be formed from any metal material. For example, various embodiments may form the liner 412 using metals such as Ni, Ti, Au, Pt, Mo, Sb, Sn, Bi, Pt, Pd, Sn, TiN, W, Co, Ru, and/or the like.

In order to further prevent damage to the 2D material 404, the deposition process may use relatively low-power and relatively low pressures during the PVD process. For example, some embodiments may use a power range of between about 100 W to about 500 W with a corresponding pressure range of about 0.1 mTorr to about 3.0 mTorr. Some embodiments may use a power range of between about 200 W to about 300 W with a corresponding pressure range of about 0.1 mTorr to about 0.5 mTorr. Some embodiments may use a power of about 220 W with a corresponding pressure of about 0.3 mTorr. The power may be less than about 500 W, less than about 400 W, less than about 300 W, less than about 200 W, less than about 100 W, and so forth. Additionally, the pressure may be less than about 3.0 mTorr, less than about 2.5 mTorr, less than about 2.0 mTorr, less than about 1.5 mTorr, less than about 1.0 mTorr, less than about 0.5 mTorr, and so forth.

The temperature of the deposition process for forming the liner 412 may be maintained at between about 200° C. and about 500° C. For example, the temperature may be between about 200° C. and about 250° C., between about 250° C. and about 300° C., between about 300° C. and about 350° C., between about 350° C. and about 400° C., between about 400° C. and about 450° C., between about 450° C. and about 500° C., and so forth. The temperature may also include any interval within the intervals described above (e.g., between about 300° C. and about 500° C.). The temperature may also include any individual value within the intervals described above (e.g., about 350° C.). These temperature ranges have been shown to help prevent diffusion defects during deposition as described above in FIG. 2B.

Some embodiments may perform a multi-cycle deposition process with a preheat step to preheat the substrate up to the operating temperature in the ranges described above. This preheating promotes wetting and improves the step coverage on the sidewall with reduced overhang. To further improve step coverage, some embodiments may angle the deposition process to direct the deposition towards the sidewalls of the feature. For example, a target for the PVD process may be positioned at an angle relative to the substrate. As the substrate rotates during the PVD process, the angled target may cause the PVD process to better coat the sidewalls of the feature. The tilt angle may be between about 20° and about 40° relative to an orthogonal or normal axis of the pedestal and/or substrate. For example, the tilt angle may be between about 20° and about 25°, between about 25° and about 30°, between about 30° and about 35°, between about 35° and about 40°, between about 40° and about 45°, between about 45° and about 50°, and so forth. The angle may also include any interval within the intervals described above (e.g., between about 25° and about 35°). The angle may also include any individual value within the intervals described above (e.g., about 30°).

The process for forming the liner 412 may be performed until the liner 412 reaches a target thickness. The thickness of the liner may be between about 10 Å and about 500 Å. For example, the thickness of the liner may be between about 10 Å and about 50 Å, between about 50 Å and about 100 Å, between about 100 Å and about 150 Å, between about 150 Å and about 200 Å, between about 200 Å and about 250 Å, between about 250 Å and about 300 Å, between about 300 Å about 350 Å, between about 350 Å about 400 Å, between about 400 Å and about 450 Å, between about 450 Å about 500 Å, and so forth. The thickness may also include any interval within the intervals described above (e.g., between about 30 Å and about 100 Å). The thickness may also include any individual value within the intervals described above (e.g., about 50 Å).

FIG. 4E illustrates a metal fill operation, according to some embodiments. After forming the liner 412, the process of filling the feature 410 with the metal may also include performing a metal fill. For example, the metal fill may fill an interior portion or center of the feature 410 that remains inside of the liner 412. The liner 412 may serve to protect the 2D material 404 during this metal fill operation. Additionally, the selection of a metal for the liner 412 may largely determine the performance of the metal contact. Therefore, different metal fill operations may be compatible with this process after the liner 412 is formed.

By way of example, an ALD conformal fill process may be used. Other example processes may use a PVD or a CVD process. Metals that may be used for the metal fill process may include any metal, such as W, Ru, Co, Mo, Cu, TiN, TaN, and/or the like. The metal fill process may angle the target of the deposition, or may use an angle of 0° such that the deposition process is aimed directly at the surface of the substrate. Temperatures of the metal fill process may range from room temperature to about 500° C., about 300° C. to about 400° C., about 200° C. to about 500° C., and so forth. Pressures of the metal fill process may range from about 0.1 Torr to about 100 Torr, between about 1 Torr and about 50 Torr, between about 10 Torr and about 30 Torr, and so forth, depending on the type of process.

FIG. 4F illustrates an example of the semiconductor device 400 with additional components, according to some embodiments. FIG. 4F is provided only to illustrate how the formation of the metal contacts 420, 422 described above may be part of an operating device. In this example, the metal contacts 420, 422 may be part of a transistor. A gate 424 may be formed between the metal contacts 420, 422. The metal contacts 420, 422 may form a drain and/or source for the transistor. The formation of the gate 424 and other components illustrated in FIG. 4F is beyond the scope of this disclosure.

The implementation of the method 300 illustrated above in FIGS. 4A-4F describes the formation of a planar device where the features are vertical holes with the 2D material exposed at the bottom of the vertical holes, and where the metal fills the vertical hole to form an electrode of the semiconductor device. Additionally or alternatively, the method 300 may also be used to form a vertical or 3D device, such as a 3D NAND memory device. In a vertical device, the feature may include a vertical channel hole that is conformally lined with the 2D material. The metal that substantially fills the vertical channel hole inside of the 2D material may form an electrode in the channel hole that contacts the 2D material.

When forming a 3D vertical device, the method 300 may again form a layer of the 2D material (302). FIG. 5A illustrates the formation of a 2D material 504 in a channel hole of a semiconductor device 500, according to some embodiments. The semiconductor device 500 may include a substrate 502 that is part of a 3D NAND device. Therefore, the substrate 502 may include many different layers, including nitride layers, oxide layers, metal layers, and so forth, that are not shown explicitly in FIG. 5A. The substrate 502 may have a plurality of features, such as the feature 511 that form holes for individual memory devices in a 3D NAND array. These features may be etched through the layers of the substrate 502 as illustrated in FIG. 5A.

The 2D material 504 may be formed conformally on the substrate 502. For example, the 2D material 504 may be formed along a top surface of the substrate 502. The 2D material 504 may also be formed along the vertical sidewalls of the feature 511. The 2D material 504 may extend down the entire depth of the feature 511. The type of 2D material 504 and the process for forming the 2D material 504 may be similar to the description of the 2D material 404 above in relation to FIG. 4A, and any of the concepts described above are also applicable to the 2D material 504 of FIG. 5A.

The method 300 may also include forming a layer of an insulating material on the 2D material (304). FIG. 5B illustrates an insulating material 506 that is formed on the 2D material 504, according to some embodiments. A fill operation may be used to fill the feature 511 with the insulating material 506. The insulating material 506 may be any dielectric material, such as silicon dioxide. As depicted in FIG. 5B, the insulating material 506 may extend above the top surface of the feature 511 and/or the top surface of the 2D material 504. The type of insulating material 506 and the process for forming the insulating material 506 may be the similar to the insulating material 406 described above in FIG. 4B, and any of the concepts described above are also applicable to the insulating material 506 of FIG. 5B.

The method 300 may also include etching away a portion of the insulating material to again form the feature expose a surface of the 2D material (306). FIG. 5C illustrates an etch process 509 that may be used to remove a portion of the insulating material 506 from the semiconductor device 500 according to some embodiments. The etch process 509 may be very selective to the 2D material 504 as described above. Therefore, the etch process 509 may substantially remove the insulating material 506 above the surface of the feature 511 and expose the top surface of the 2D material 504 along the top of the semiconductor device 500. Additionally, the etch process 509 may remove a portion of the insulating material 506 from within the feature 511 down to a predetermined depth. For example, the insulating material 506 (e.g., an oxide) may fill a portion of the vertical channel below the predetermined depth such that the etch process stops before removing all of the insulating material 506 from the vertical channel hole. The etch process 509 for removing the insulating material 506 may be substantially similar to the etch process 409 described above in relation to FIG. 4C, and any of the concepts described above are also applicable to the etch process 509 of FIG. 5C.

The method 300 may additionally include filling the feature with the metal, such that the metal contacts the surface of the 2D material (308). FIG. 5D illustrates how a metal 510 may substantially fill the vertical channel hole inside of the 2D material 504, according to some embodiments. Since the 2D material 504 on the vertical sidewalls was exposed by the etch process 509, the metal 510 may contact the 2D material without penetrating or damaging the 2D material. The metal in the vertical channel hole may form an electrode for the semiconductor device. The metal 510 may be deposited to substantially fill the vertical channel hole, and may optionally extend above the vertical channel hole to cover a top portion of the substrate 502 as depicted in FIG. 5D. Subsequent processes, such as a chemical-mechanical polishing (CMP) process may be used to remove a portion of the metal 510 extending above the top surface of the substrate 502. As described above, the deposition of the metal 510 may include multiple steps, such as forming a liner and then performing a metal-fill process. The formation of the liner and the metal-fill process may be substantially similar to the processes described above in relation to FIG. 4D, and any of the concepts described above are also applicable to the formation of the metal 510 of FIG. 5D.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a pillar” includes a plurality of such pillars, and reference to “the layer” includes reference to one or more layers and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups. The terms “approximately,” “about,” and/or “substantially,” may refer to a nominal dimension or measurement that deviates by less than 10% of the stated value.

The foregoing description provides exemplary embodiments only, and is not intended to limit the scope, applicability, or configuration of the disclosure. Rather, the foregoing description of various embodiments will provide an enabling disclosure for implementing at least one embodiment. It should be understood that various changes may be made in the function and arrangement of elements without departing from the spirit and scope of some embodiments as set forth in the appended claims.

Specific details are given in the foregoing description to provide a thorough understanding of the embodiments. However, it will be understood that the embodiments may be practiced without these specific details. For example, circuits, systems, networks, processes, and other components may have been shown as components in block diagram form in order not to obscure the embodiments in unnecessary detail. In other instances, well-known circuits, processes, algorithms, structures, and techniques may have been shown without unnecessary detail in order to avoid obscuring the embodiments.

Also, it is noted that individual embodiments may have been described as a process which is depicted as a flowchart, a flow diagram, a data flow diagram, a structure diagram, or a block diagram. Although a flowchart may have described the operations as a sequential process, many of the operations can be performed in parallel or concurrently. In addition, the order of the operations may be re-arranged. A process is terminated when its operations are completed, but could have additional steps not included in a figure. A process may correspond to a method, a function, a procedure, a subroutine, a subprogram, etc. When a process corresponds to a function, its termination can correspond to a return of the function to the calling function or the main function.

The term “computer-readable medium” includes, but is not limited to portable or fixed storage devices, optical storage devices, wireless channels and various other mediums capable of storing, containing, or carrying instruction(s) and/or data. A code segment or machine-executable instructions may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc., may be passed, forwarded, or transmitted via any suitable means including memory sharing, message passing, token passing, network transmission, etc.

Furthermore, embodiments may be implemented by hardware, software, firmware, middleware, microcode, hardware description languages, or any combination thereof. When implemented in software, firmware, middleware or microcode, the program code or code segments to perform the necessary tasks may be stored in a machine readable medium. A processor(s) may perform the necessary tasks.

Additionally, for the purposes of illustration, methods were described in a particular order. It should be appreciated that in alternate embodiments, the methods may be performed in a different order than that described. It should also be appreciated that the methods described above may be performed by hardware components or may be embodied in sequences of machine-executable instructions, which may be used to cause a machine, such as a general-purpose or special-purpose processor or logic circuits programmed with the instructions to perform the methods. These machine-executable instructions may be stored on one or more machine readable mediums, such as CD-ROMs or other type of optical disks, floppy diskettes, ROMs, RAMS, EPROMs, EEPROMs, magnetic or optical cards, flash memory, or other types of machine-readable mediums suitable for storing electronic instructions. Alternatively, the methods may be performed by a combination of hardware and software.

What is claimed is:

1. A semiconductor device comprising:
a channel layer comprising a two-dimensional (2D) material and forming a channel for the semiconductor device;
an insulating layer formed over the channel layer, wherein the insulating layer defines a feature that extends through the insulating layer down to the channel layer; and
a metal that fills the feature, wherein the metal contacts a top surface of the 2D material of the channel layer.

2. The semiconductor device of claim 1, wherein the metal contacts the top surface of the 2D material without penetrating or damaging the 2D material.

3. The semiconductor device of claim 1, wherein the 2D material comprises a Transition-Metal Dichalcogenide (TMD) monolayer or bilayer.

4. The semiconductor device of claim 1, wherein the 2D material comprises a monolayer or bilayer of molybdenum disulfide (MoS₂).

5. The semiconductor device of claim 1, wherein the channel layer forms a planar channel layer, and the metal forms a drain or source for the semiconductor device.

6. The semiconductor device of claim 1, wherein a vertical side of the channel layer is free of contact with the metal.

7. A semiconductor device comprising:
a vertical channel hole defined in the semiconductor device;
a two-dimensional (2D) material that conformally lines the vertical channel hole; and
a metal in the vertical channel hole that contacts the 2D material and forms an electrode for the semiconductor device.

8. The semiconductor device of claim 7, wherein the metal contacts the 2D material without penetrating or damaging the 2D material.

9. The semiconductor device of claim 7, wherein the metal substantially fills the vertical channel hole inside of the 2D material.

10. The semiconductor device of claim 7, wherein the 2D material also conformally lines a top surface of the semiconductor device between vertical channel holes.

11. The semiconductor device of claim 7, further comprising an oxide layer that fills a portion of the vertical channel hole below the metal.

12. A method of forming a semiconductor device, the method comprising:
forming a layer of a two-dimensional (2D) material;
forming a layer of an insulating material on the 2D material;
etching away a portion of the insulating material to form a feature and expose a surface of the 2D material; and
filling the feature with a metal, wherein the metal contacts the surface of the 2D material.

13. The method of claim 12, wherein etching away the portion of the insulating material comprises performing a plasma-free vapor etch.

14. The method of claim 12, wherein etching away the portion of the insulating material comprises maintaining a temperature of less than or about 45° C. such that 2D material is free of oxidation.

15. The method of claim 12, wherein etching away the portion of the insulating material comprises providing an HF etch gas with an NH3 carrier gas with a flow rate ratio of approximately 1:1.

16. The method of claim 12, wherein etching away the portion of the insulating material comprises increasing a temperature of the semiconductor device by moving the semiconductor device closer to a top plate of a processing chamber and performing an anneal of between about 110° C. and about 130° C.

17. The method of claim 12, wherein filling the feature with the metal comprises a target tilt angle of between about 30° and about 40°.

18. The method of claim 12, wherein filling the feature with the metal comprises:
forming a metal liner using a physical vapor deposition (PVD) process performed with a power that is less than or about 500 W and a pressure less than or about 0.1 Torr; and
filling the feature with a metal fill material.

19. The method of claim 12, wherein the semiconductor device comprises a planar device, the feature comprises a vertical hole with the 2D material exposed at a bottom of the vertical hole, and the metal fills the vertical hole to form an electrode of the semiconductor device.

20. The method of claim 12, wherein the semiconductor device comprises a three-dimensional (3D) NAND memory device, the feature comprises a vertical channel hole that is conformally lined with the 2D material, and the metal substantially fills the vertical channel hole inside of the 2D material.
